(19) United States
(12) Patent Application Publication
(10) Pub. No.: US 2025/0068819 A1
(43) Pub. Date: Feb. 27, 2025

(54) NON-RECTANGULAR CELL LAYOUT METHOD AND SYSTEM

(71) Applicant: TAIWAN SEMICONDUCTOR MANUFACTURING COMPANY, LTD., Hsinchu (TW)

(72) Inventors: Ranjith KUMAR, Hsinchu (TW); Mohammed Zackriya VANAIKAR, Hsinchu (TW)

(21) Appl. No.: 18/452,947

(22) Filed: Aug. 21, 2023

(51) Int. Cl. G06F 30/392; G06F 30/31

(52) U.S. Cl. CPC G06F 30/392; G06F 30/31

(57) ABSTRACT

A method includes arranging first and second rows of gate regions in a cell. The first row has a first width extending from first to last gate regions and equal to a first multiple of a gate region pitch. The second row has a second width extending from first to last gate regions and equal to a second multiple of the gate region pitch greater than the first multiple. The method includes defining first through fourth cell border segments by extending the first and second segments along the first and last gate regions of the first row, and extending the third and fourth segments along the first and last gate regions of the second row, whereby the border is non-rectangular based on one or both of the first and third segments or the second and fourth segments being unaligned with each other, and storing the cell in a storage device.

### BACKGROUND

The ongoing trend in miniaturizing integrated circuits (ICs) has resulted in progressively smaller devices which consume less power, yet provide more functionality at higher speeds than earlier technologies. Miniaturization has been achieved through design and manufacturing innovations tied to increasingly strict specifications. Various electronic design automation (EDA) tools are used to generate, revise, and verify designs for semiconductor devices while ensuring that design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts an IC layout diagram, in accordance with some embodiments.

FIG. 2 depicts an IC layout diagram, in accordance with some embodiments.

FIG. 3 depicts an IC layout diagram, in accordance with some embodiments.

FIG. 4 depicts an IC layout diagram, in accordance with some embodiments.

FIG. 5 depicts an IC layout diagram, in accordance with some embodiments.

FIGS. 6A-6C depict IC layout diagrams, in accordance with some embodiments.

FIGS. 7A and 7B depict IC layout diagrams, in accordance with some embodiments.

FIG. 8 depicts an IC layout diagram, in accordance with some embodiments.

FIG. 9 is a flowchart of a method of generating an IC layout diagram, in accordance with some embodiments.

FIG. 10 is a block diagram of an IC design system, in accordance with some embodiments.

FIG. 11 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) layout diagram, method, and IC design system are directed to non-rectangular standard cells in which adjacent rows have unequal widths based on differing numbers of gate regions spaced according to a gate region pitch. Compared to rectangular cells, the non-rectangular cell configurations enable improved power, performance, and area (PPA) metrics by eliminating unused spaces and shortening internal routing elements, e.g., paths corresponding to external and internal signals having timing criticality, as discussed below.

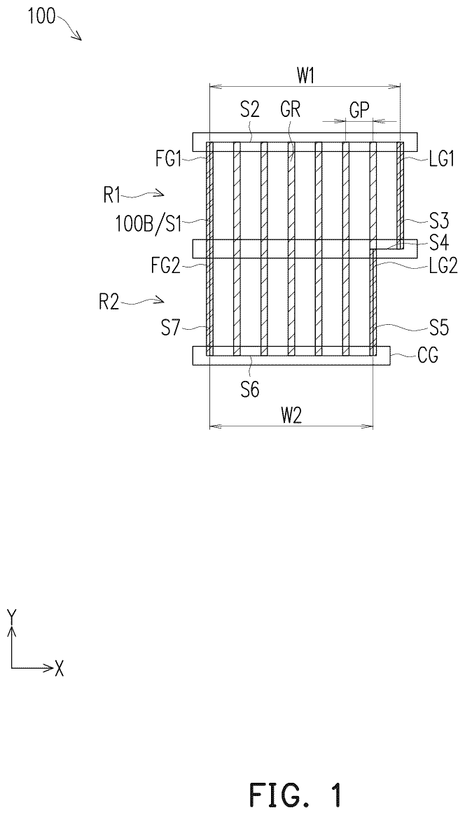

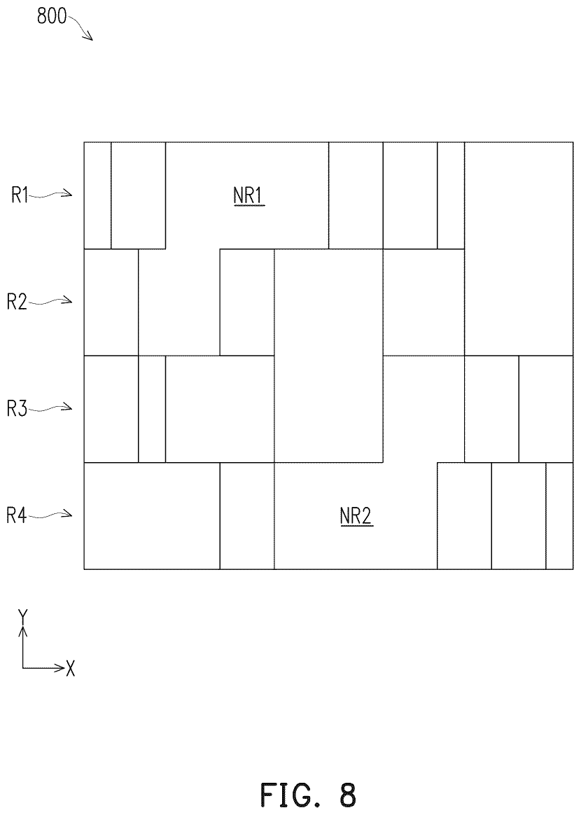

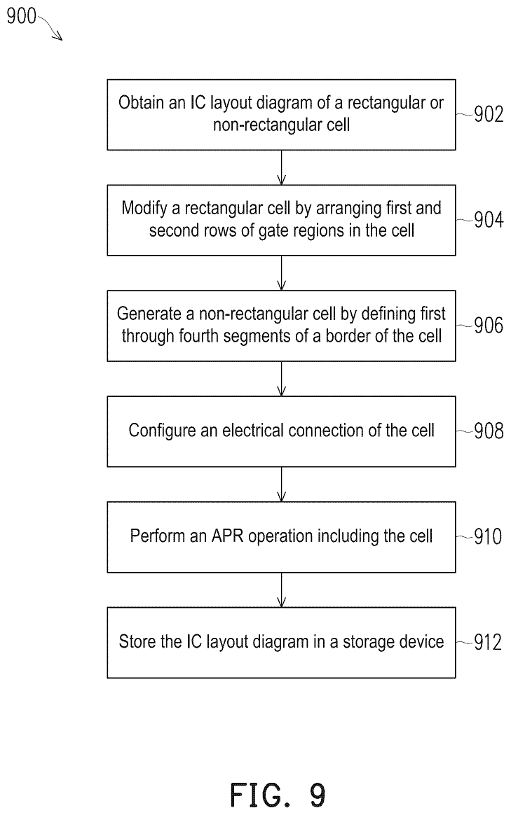

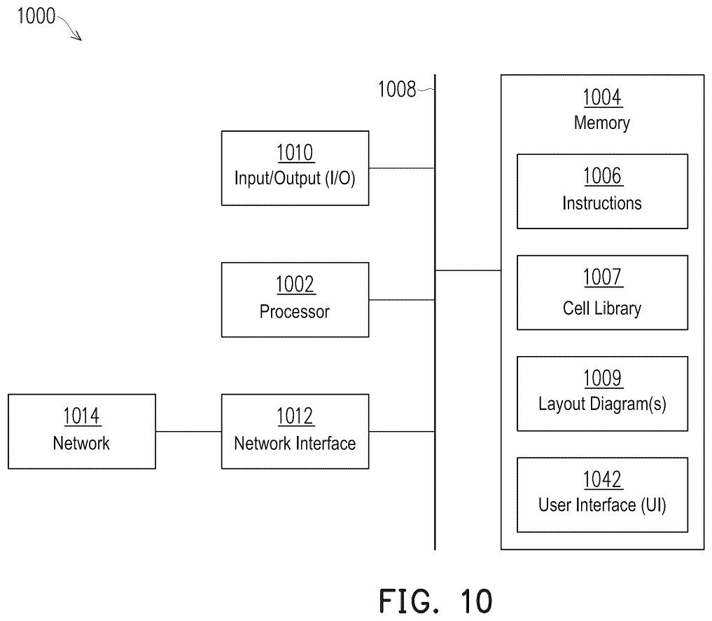

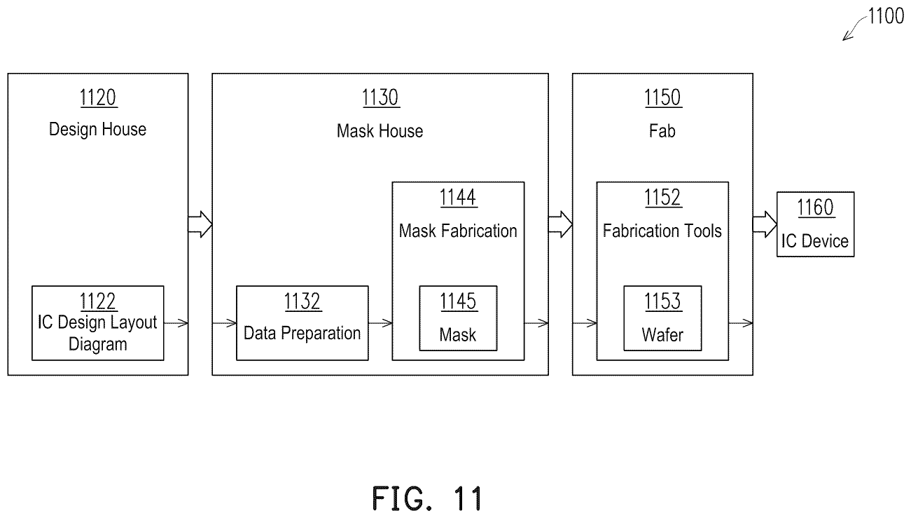

As discussed below, FIGS. 1-7B depict IC layout diagrams 100-700B of non-limiting examples of non-rectangular cells, also referred to as cells 100-700B in some embodiments, FIG. 8 depicts an IC layout floorplan 800 including non-limiting examples of non-rectangular cells, FIG. 9 is a flowchart of a method 900 of generating an IC layout diagram, e.g., an IC layout diagram 100-700B, FIG. 10 is a block diagram of an IC design system 1000, e.g., an EDA system 1000, configured to perform some or all of the operations of method 900, and FIG. 11 is a block diagram of an IC manufacturing system and associated IC manufacturing flow 1100 by which one or more IC structures are manufactured based at least in part on one or more of IC layout diagrams 100-800.

Each of FIGS. 1-8 depicts a plan view of a corresponding IC layout diagram 100-800 along with X and Y directions and is simplified for the purpose of illustration. In various embodiments, a given IC layout diagram 100-800 includes one or more features, e.g., active regions, source/drain (S/D) structures, isolation features, internal routing elements, or the like, that are not depicted for the purpose of clarity.

In the embodiment depicted in FIG. 1, cell 100 includes adjacent rows R1 and R2 of gate regions GR (a single instance labeled for clarity). A cell, e.g., cell 100, also referred to as a standard cell or standard functional cell in some embodiments, is an IC layout diagram including a specific internal arrangement of components, e.g. gate regions GR, configured to provide (in operation) a corresponding common, low-level function, e.g., a logic function such as an inverter, NAND, NOR, XOR, D-latch, and-or-invert (AOI), or-and-invert (OAI), multiplexer, flip-flop, a decoupling capacitor (DeCap), or the like.

In some applications, e.g., an automatic placement and routing (APR) operation, electronic design automation (EDA) tools are used to select standard functional cells from standard cell libraries and place the standard functional cells into an initial layout along with non-standard cells (if any). EDA tools are also used to perform routing by which the standard functional cells and the non-standard cells are connected using one or more metal layers and corresponding vias and contacts. EDA tools are further used to test the routing. Depending upon the test results, the selection, placement and routing of the standard and non-standard cells is revised. In at least some embodiments, the overall selection, placement, routing and testing (SPRT) process is iterative. Eventually, the SPRT process iterations converge to a finalized layout.

The total of two adjacent rows R1 and R2 in cell 100 depicted in FIG. 1 is a non-limiting example provided for the purpose of illustration. In some embodiments, cell 100 includes more than two adjacent rows.

Each of rows R1 and R2 corresponds to a plurality of gate regions GR spaced in accordance with a gate region pitch GP, also referred to as a pitch GP in some embodiments. Row R1 includes instances of gate region GR extending in the X direction from a first gate region FG1 to a second gate region LG1, and row R2 includes instances of gate region GR extending in the X direction from a first gate region FG2 to a second gate region LG2.

A gate region GR is a region in an IC layout diagram, e.g., cell 100, that at least partially defines a gate structure, e.g., a gate electrode isolated from adjacent features by one or more gate dielectric layers, in a manufacturing process used to manufacture an IC corresponding to the IC layout diagram, e.g., manufacturing flow 1100 discussed below.

Some or all of the instances of gate region GR are components of IC devices configured to provide the predetermined function of cell 100 and are not further depicted for the purpose of clarity. In some embodiment, a row, e.g., row R1 or R2, is referred to as a row of gate regions or a row of IC devices, the IC devices including the corresponding instances of gate regions GR.

In the embodiment depicted in FIG. 1, upper and lower boundaries of a given row, e.g., row R1 or R2, include instances of a cut-gate region CG (a single instance labeled for the purpose of clarity), also referred to as a cut-poly region CG in some embodiments. A cut-gate region CG is a region in the IC layout diagram that at least partially defines gate structure discontinuities formed by using a manufacturing process, e.g., one or more etch operations, to remove gate electrode and/or dielectric layer portions subsequent to their formation. As depicted in FIG. 1 instances of gate region GR aligned along the Y direction are thereby electrically isolated from each other based on the instances of cut-gate regions CG.

In the embodiment depicted in FIG. 1, each instance of cut-gate region CG extends across an entirety of each of rows R1 and R2. In various embodiments, a given instance of cut-gate region CG is not present, extends along a portion of a row, or includes multiple segments whereby one or more pairs of instances of gate region GR aligned along the Y direction are electrically connected to each other.

In some embodiments, one or more instances of gate region GR are dummy gate regions corresponding to gate structures that are not included in IC devices, e.g., by being positioned in accordance with pitch GP to provide loading uniformity in one or more manufacturing processes. In some embodiments, each of gate regions FG1, LG1, FG2, and LG2 is a dummy gate region.

In the embodiment depicted in FIG. 1, row R1 includes a total of eight instances of gate region GR and row R2 includes a total of seven instances of gate region GR such that cell 100 includes a total of 15 instances of gate region GR, an odd number based on rows R1 and R2 having total numbers differing by one.

In various embodiments, cell 100 includes rows including other total numbers of gate regions, e.g., other total numbers differing by one or by more than one. In some embodiments, cell 100 includes a total number of instances of gate regions GR that is an even number.

In the embodiment depicted in FIG. 1, gate regions FG1 and FG2 are aligned in the Y direction, and each instance of gate region GR in row R2 is aligned with a corresponding instance of gate region GR in row R1. In some embodiments, gate regions FG1 and FG2 are not aligned in the Y direction, gate regions LG1 and LG2 are aligned in the Y direction, and each instance of gate region GR in row R2 is aligned with a corresponding instance of gate region GR in row R1.

In some embodiments, gate regions FG1 and FG2 are not aligned in the Y direction, gate regions LG1 and LG2 are not aligned in the Y direction, and a subset of instances of gate region GR in row R2 are aligned with corresponding instances of gate region GR in row R1, a configuration corresponding to rows R1 and R2 being offset along the X direction.

In some embodiments, cell 100 includes one or more rows adjacent to row R1 and/or R2, and corresponding additional instances of gate regions GR have one or more alignments relative to rows R1 and/or R2 and/or to each other analogous to those of rows R1 and R2 relative to each other.

The total number of instances of gate region GR in a given row corresponds to a width in the X direction, the width corresponding to a multiple of pitch GP in accordance with the total number. In the non-limiting example depicted in FIG. 1, row R1 has a width W1 corresponding to pitch GP and a multiple of eight instances of gate region GR, and row R2 has a width W2 corresponding to pitch GP and a multiple of seven instances of gate region GR.

In accordance with the configurations of instances of gate region GR discussed above, cell 100 includes a border 100B including segments S1-S7. In the embodiment depicted in FIG. 1, segment S1 extends in the Y direction along gate region FG1, segment S2 extends in the X direction along width W1, segment S3 extends in the Y direction along gate region LG1, segment S4 extends in the X direction along a portion of width W1 equal to a difference between widths W1 and W2, segment S5 extends in the Y direction along gate region LG2, segment S6 extends in the X direction along width W2, and segment S7 extends in the Y direction along gate region FG2, thereby being aligned with segment S1 along the Y direction.

In various embodiments, a cell, e.g., cell 100, includes a border including segments otherwise arranged in accordance with one or more pairs of rows of unequal total numbers of instances of gate regions GR. In some embodiments, cell 100 corresponds to one of non-limiting example cells 200-700B discussed below, in which individual segments of corresponding borders 200B-700BB are not labeled for the purpose of clarity.

By including rows R1 and R2 having differing widths based on differing total numbers of instances of gate region GR as discussed above, cell 100 is configured as a non-rectangular cell capable of having reduced area or otherwise having improved PPA metrics, e.g., a reduced power level for a same or increased area, compared to a rectangular cell corresponding to a cell function equivalent to that of cell 100.

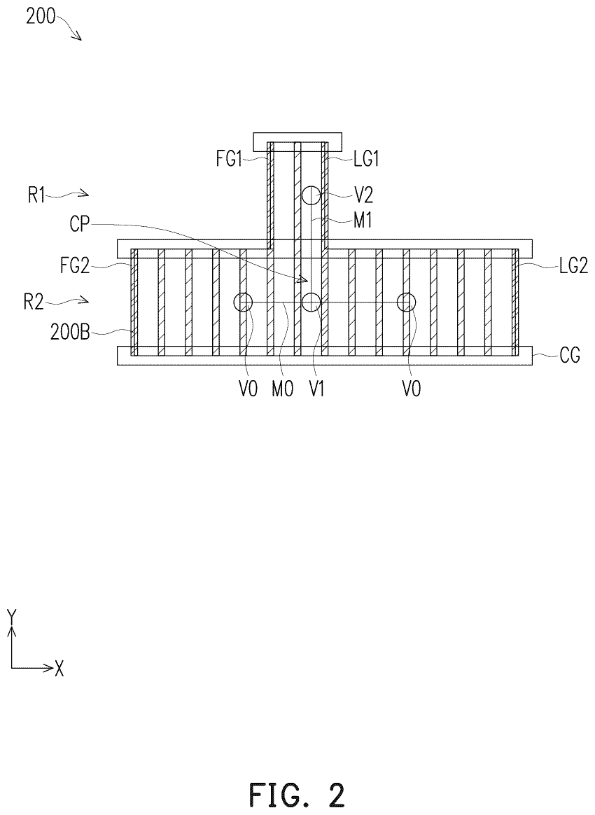

FIG. 2 depicts cell 200, in accordance with some embodiments, including row R1 extending from gate region FG1 to gate region LG1, row R2 extending from gate region FG2 to gate region LG2, and instances of cut-gate region CG, each discussed above with respect to FIG. 1.

Cell 200 also includes a critical path CP including via regions V0, V1, and V2, a metal region M0 extending along the X direction, and a metal region M1 extending along the Y direction, as discussed below.

A via region, e.g., via region V0, V1, or V2, is a region in the IC layout diagram that at least partially defines a via or other structure capable of forming an electrical connection, e.g., a structure including a metal such as copper, to an underlying feature, e.g., a gate electrode corresponding to an instance of gate region GR, an S/D structure of an IC device, or an underlying metal segment.

A metal region, e.g., metal region M0 or M1, is a region in the IC layout diagram that overlaps one or more features, e.g., a corresponding instance of via region V0 or V1, and at least partially defines a metal segment overlying and electrically connected to an underlying via structure corresponding to an instance of a corresponding via region V0 or V1. In some embodiments, a metal segment M1, also referred to as a metal-one segment M1 in some embodiments, is included in a lowest metal layer of a routing process, e.g., an APR process, corresponding to the IC layout diagram.

A critical path, e.g., critical path CP or a signal path SP discussed below, also referred to as a critical route in some embodiments, is an electrical connection including one or more vias and/or metal segments configured to propagate one or more signals in accordance with one or more critical design criteria, e.g., based on signal speed, timing, and/or loss, power dissipation, heat generation, electromigration risk, or the like. In some embodiments, the one or more design criteria of a critical path include a maximum resistance, capacitance, and/or combined resistance and capacitance (RC) associated with a minimum signal speed, phase shift, or loss and/or a maximum power dissipation.

In the embodiment depicted in FIG. 2, each instance of via region V0 overlaps a corresponding instance of gate region GR (not labeled) in row R2, metal region M0 overlaps each instance of via region V0, via region V1 overlaps metal region M0 at a location between locations at which the instances of via region V0 overlap metal region M0, metal region M1 overlaps via region V1, and via region V2 overlaps metal region M1 at a location in row R1.

By the configuration depicted in FIG. 2, cell 200 includes features configured to at least partially define critical path CP as an electrical connection from via region V2 (capable of being included in an electrical connection external to cell 200, e.g., in an APR operation) positioned in row R1 to the corresponding instances of gate region GR in row R2 through metal region M1, via region v1, metal region M0, and the instances of via region V0.

As depicted in FIG. 2, cell 200 includes border 200B including segments (not labeled) extending along the corresponding portions of rows R1 and R2 configured as discussed above.

Because via region V1 overlaps metal region M0 near a midpoint between the instances of via region V0, a length of critical path CP between via region V2 and a given instance of via region V0 is shorter than a corresponding length in other approaches, e.g., rectangular cells including a single row.

Cell 200 is thereby configured as a non-rectangular cell capable of including the electrical connection of critical path CP including reduced parasitic resistance and/or capacitance, e.g., based on a shorter electrical path length, compared to a rectangular cell, e.g., including a single row, corresponding to a cell function equivalent to that of cell 200.

Cell 200 thereby includes critical path CP further configured to, in operation, propagate a signal received at via region V2 to each of the gates underlying via regions V0 having timing that is more closely balanced than in other approaches, e.g., those in which a signal is propagated along a single row.

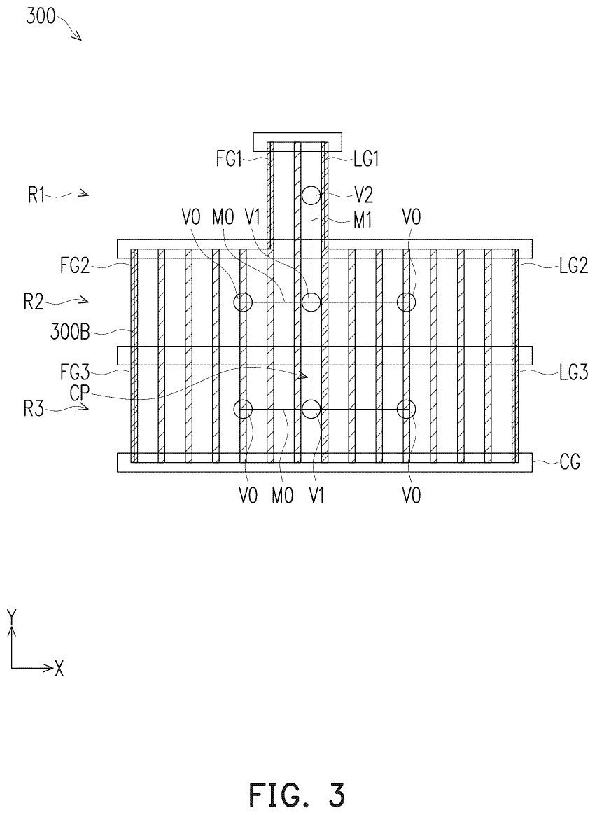

FIG. 3 depicts cell 300, in accordance with some embodiments, including row R1 extending from gate region FG1 to gate region LG1, row R2 extending from gate region FG2 to gate region LG2, and instances of cut-gate region CG, via regions V0, V1, and V2, and metal regions M0 and M1, each discussed above.

Cell 300 also includes a row R3 including instances of gate regions GR (not labeled) extending from a gate region FG3 to a gate region LG3.

Compared to cell 200, cell 300 includes critical path CP including metal region M1 extending into row R3 from row R2 and overlapping an instance of via region V1, which further overlaps an instance of metal region M1 at a location in row R3 between locations at which the instance of metal region M0 overlaps instances of via region V0, each of which overlaps a corresponding instance of gate region GR.

By the configuration depicted in FIG. 3, cell 300 includes features configured to at least partially define critical path CP as an electrical connection from via region V2 positioned in row R1 to the corresponding instances of gate region GR in each of rows R2 and R3 through metal region M1 and the instances of via region v1, metal region M0, and via region V0.

As depicted in FIG. 3, cell 300 includes border 300B including segments (not labeled) extending along the corresponding portions of rows R1-R3 configured as discussed above.

Cell 300 is thereby configured as a non-rectangular cell capable of realizing the benefits discussed above with respect to FIG. 2, including the electrical connection including reduced parasitic resistance and/or capacitance, e.g., based on a shorter electrical path length, compared to a rectangular cell, e.g., including a total of two rows, corresponding to a cell function equivalent to that of cell 300.

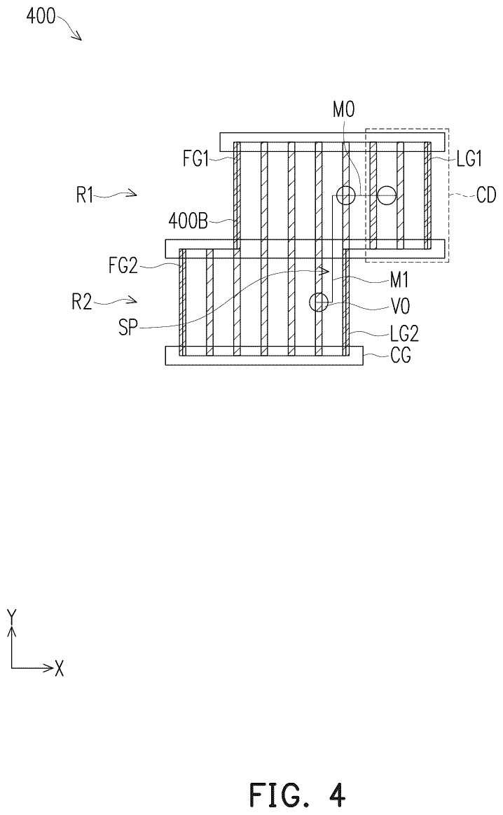

FIG. 4 depicts cell 400, in accordance with some embodiments, including row R1 extending from gate region FG1 to gate region LG1, row R2 extending from gate region FG2 to gate region LG2, and instances of cut-gate region CG, via region V0 (a single instance labeled for clarity), and metal regions M0 (a single instance labeled for clarity) and M1, each discussed above.

Cell 400 includes a critical device CD including gate region LG1 and two instances of gate region GR (not labeled). A critical device, e.g., critical device CD, is a circuit portion such as an oscillator, amplifier, or buffer configured to output, e.g., generate, one or more signals on a critical path in accordance with one or more critical design criteria as discussed above.

An instance of via region V0 positioned in critical device CD corresponds to a signal source, and the instances of via region V0 external to critical device CD correspond to sink locations of the signal, the instances of via regions V0 and metal regions M0 and M1 thereby being configured as an internal signal path SP.

As depicted in FIG. 4, cell 400 includes border 400B including segments (not labeled) extending along the corresponding portions of rows R1 and R2 configured as discussed above.

Cell 400 is thereby configured as a non-rectangular cell capable of including the internal signal path SP including reduced parasitic resistance and/or capacitance, e.g., based on a shorter electrical path length, compared to a rectangular cell, e.g., including a critical device positioned to include gate region FG1, corresponding to a cell function equivalent to that of cell 400. In some embodiments, cell 400 is thereby configured as a non-rectangular cell further capable of having reduced area compared to a rectangular cell corresponding to a cell function equivalent to that of cell 400.

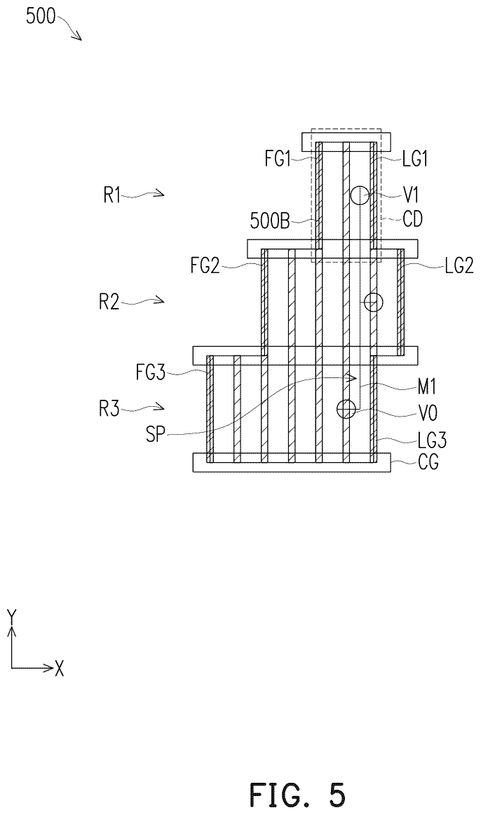

FIG. 5 depicts cell 500, in accordance with some embodiments, including row R1 extending from gate region FG1 to gate region LG1, row R2 extending from gate region FG2 to gate region LG2, row R3 extending from gate region FG3 to gate region LG3, instances of cut-gate region CG, via regions V0 (a single instance labeled for clarity) and V1, and metal regions M0 (a single instance labeled for clarity) and M1, and critical device CD, each discussed above.

Compared to cell 400, cell 500 includes critical device CD positioned in row R1 separate from other IC devices positioned in rows R2 and R3, and includes internal signal path SP extending from critical device CD in row R1 to each of the instances of via region V0 in rows R2 and R3.

As depicted in FIG. 5, cell 500 includes border 500B including segments (not labeled) extending along the corresponding portions of rows R1-R3 configured as discussed above.

Cell 500 is thereby configured as a non-rectangular cell capable of including the internal signal path SP including reduced parasitic resistance and/or capacitance, e.g., based on a shorter electrical path length, compared to a rectangular cell, e.g., including a critical device positioned to include gate region FG2, corresponding to a cell function equivalent to that of cell 500. In some embodiments, cell 500 is thereby configured as a non-rectangular cell further capable of having reduced area compared to a rectangular cell corresponding to a cell function equivalent to that of cell 500.

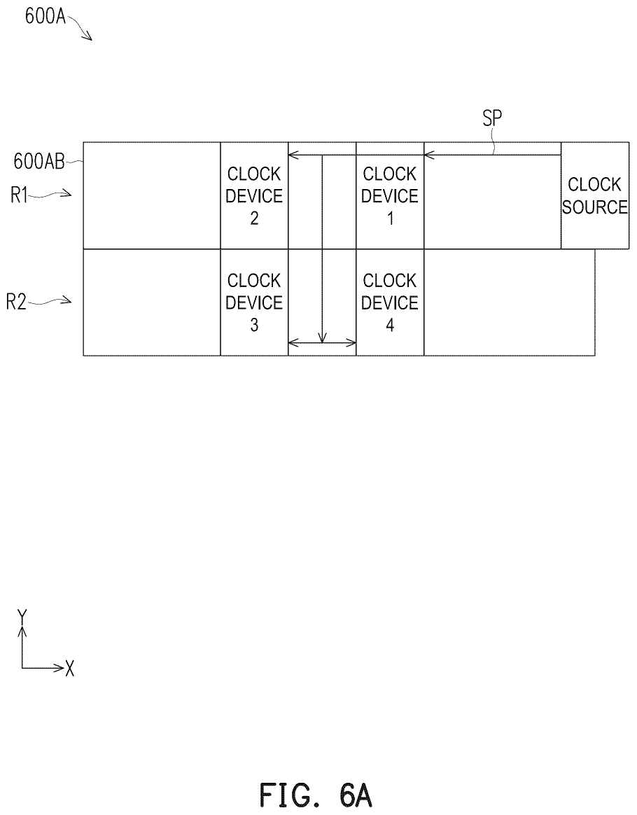

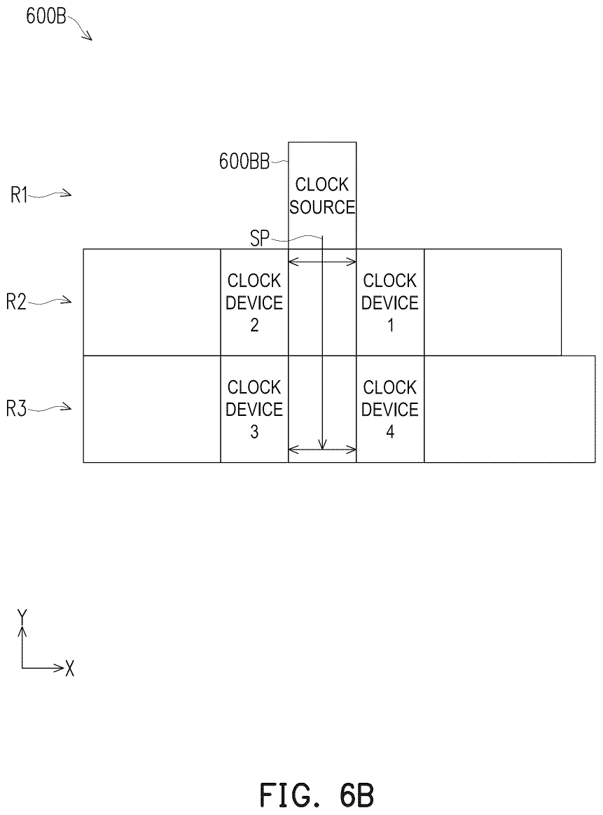

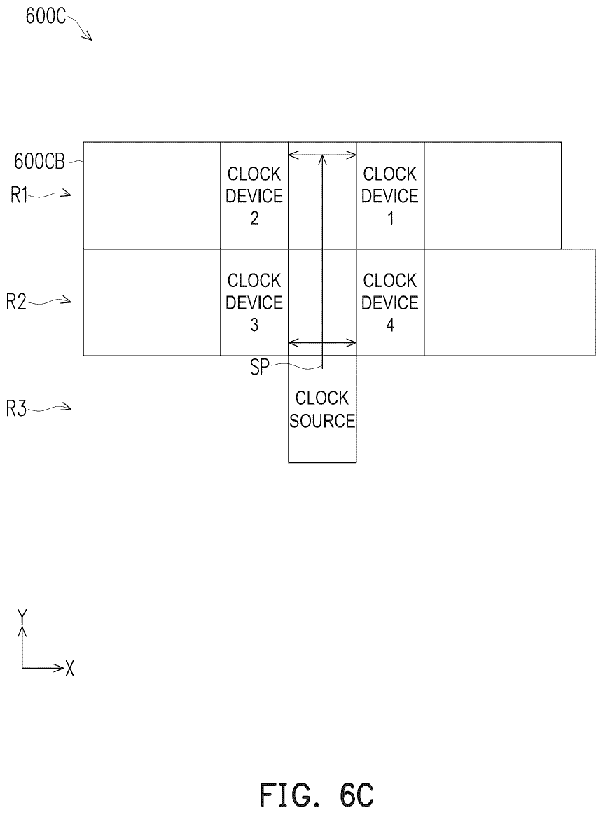

FIGS. 6A-6C depict respective cells 600A-600C, in accordance with some embodiments, each configured as a flip-flop circuit, also referred to as a flop in some embodiments, including a clock source electrically connected to each of clock devices clock device 1 through clock device 4 through signal path SP, discussed above with respect to FIGS. 4 and 5. The clock source is a non-limiting example of critical device CD discussed above with respect to FIGS. 4 and 5.

Cell 600A depicted in FIG. 6A includes rows R1 and R2, discussed above, and the clock source positioned in row R1 having a width (not labeled) greater than that of row R2. Cell 600A includes border 600AB including segments (not labeled) extending along the corresponding portions of rows R1 and R2 configured as depicted in FIG. 6A.

Cell 600A is thereby configured as a non-rectangular cell capable of having reduced area compared to a rectangular cell corresponding to a flip-flop function equivalent to that of cell 600A.

Cell 600B depicted in FIG. 6B includes rows R1-R3, discussed above, and the clock source positioned in row R1 separate from clock devices clock device 1 thorough clock device 4 positioned in rows R2 and R3, signal path SP thereby extending from row R1 to each of rows R2 and R3. Cell 600B includes border 600BB including segments (not labeled) extending along the corresponding portions of rows R1-R3 configured as depicted in FIG. 6B.

Cell 600B is thereby configured as a non-rectangular cell capable of signal path SP including reduced parasitic resistance and/or capacitance, e.g., based on a shorter electrical path length, compared to a rectangular cell, e.g., including a total of two rows, corresponding to a flip-flop function equivalent to that of cell 600B. In some embodiments, cell 600B is thereby configured as a non-rectangular cell further capable of having improved PPA metrics, e.g., a reduced area and/or power level and/or increased speed, compared to a rectangular cell corresponding to a flip-flop function equivalent to that of cell 600B.

Cell 600C depicted in FIG. 6C includes rows R1-R3, discussed above, and the clock source positioned in row R3 separate from clock devices clock device 1 thorough clock device 4 positioned in rows R1 and R2, signal path SP thereby extending from row R3 to each of rows R2 and R1. Cell 600C includes border 600CB including segments (not labeled) extending along the corresponding portions of rows R1-R3 configured as depicted in FIG. 6C.

Cell 600C is thereby configured as a non-rectangular cell capable of signal path SP including reduced parasitic resistance and/or capacitance, e.g., based on a shorter electrical path length, compared to a rectangular cell, e.g., including a total of two rows, corresponding to a flip-flop function equivalent to that of cell 600C. In some embodiments, cell 600C is thereby configured as a non-rectangular cell further capable of having reduced area compared to a rectangular cell corresponding to a flip-flop function equivalent to that of cell 600C.

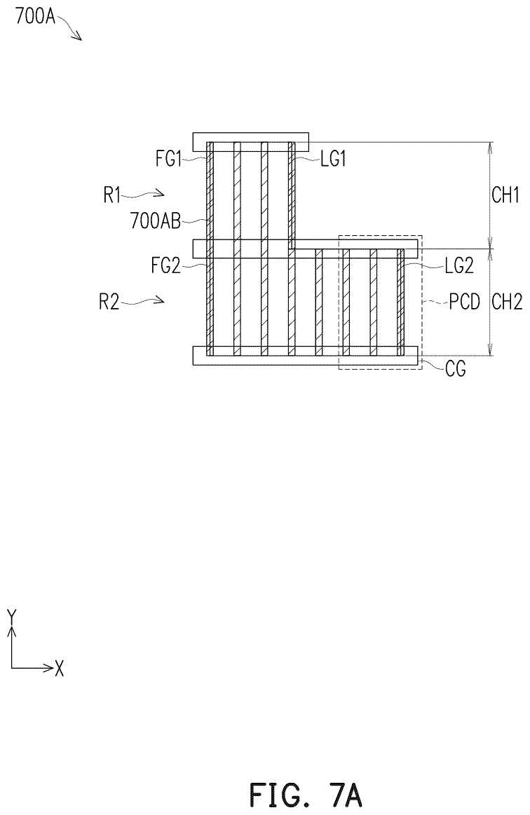

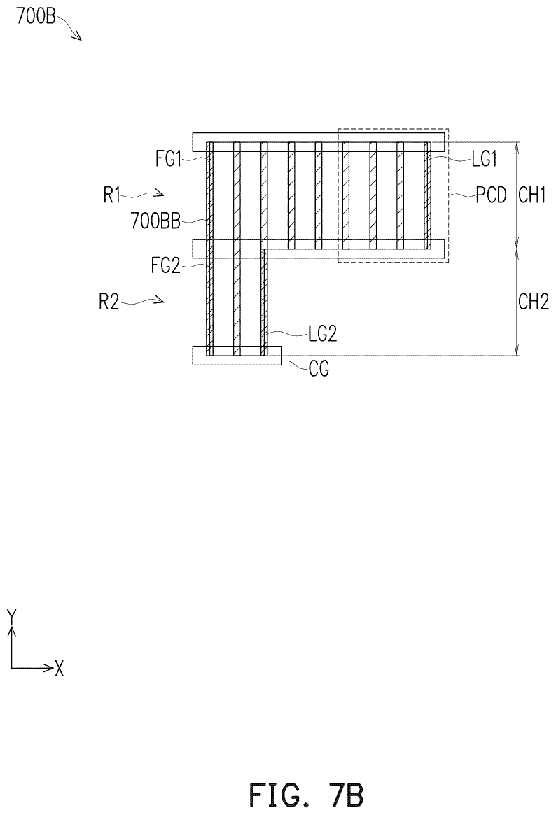

FIGS. 7A and 7BC depict respective cells 700A and 700B, in accordance with some embodiments. Each of cells 700A and 700B includes row R1 including gate regions GR (not labeled) extending from gate region FG1 to gate region LG1, row R2 including gate regions GR (not labeled) extending from gate region FG2 to gate region LG2, an instance of cut-gate region CG, each discussed above, and an instance of a performance critical device PCD.

Performance critical device PCD, also referred to as a power critical device PCD in some embodiments, is a circuit portion, e.g., one or more transistors, configured to meet one or more design criteria corresponding to critical power and/or timing requirements, e.g., a minimum current carrying capacity.

As depicted in FIGS. 7A and 7B, rows R1 and R2 have respective heights CH1 and CH2, also referred to as cell heights CH1 and CH2 in some embodiments. Height CH1 is greater than height CH2, corresponding to IC devices positioned in row R1 having larger channels and thereby being capable of higher power operation than IC devices positioned in row R2. IC devices positioned in row R1 thereby consume more power than those positioned in row R2.

In some embodiments, row R1 having height CH1 greater than height CH2 of row R2 corresponds to IC devices of rows R1 and R2 including fin field-effect transistors (FinFETs) in which row R1 corresponds to a total number of FinFET fins greater than a total number of FinFET fins corresponding to row R2.

Cell 700A depicted in FIG. 7A includes performance critical device PCD being a power critical device such that being poisoned in row R2 improves power efficiency compared to being positioned in row R1. Cell 700A includes border 700AB including segments (not labeled) extending along the corresponding portions of rows R1 and R2 configured as depicted in FIG. 7A.

Cell 700B depicted in FIG. 7B includes performance critical device PCD being a timing critical device such that being poisoned in row RI improves timing performance compared to being positioned in row R2. Cell 700B includes border 700BB including segments (not labeled) extending along the corresponding portions of rows R1 and R2 configured as depicted in FIG. 7B.

Each of cells 700A and 700B is thereby configured as a non-rectangular cell capable of including performance critical device PCD positioned to improve circuit performance compared to a rectangular cell, e.g., including a performance critical device otherwise positioned, corresponding to a cell function equivalent to that of the corresponding cell 700A or 700B. In some embodiments, cell 700A and/or 700B is thereby configured as a non-rectangular cell further capable of having reduced area compared to a rectangular cell corresponding to a cell function equivalent to that of the corresponding cell 700A or 700B.

FIG. 8 depicts IC layout diagram 800, in accordance with some embodiments. IC layout diagram 800 is also referred to as a floorplan 800 in some embodiments. IC layout diagram 800 includes rows R1-R3 discussed above and includes a row R4 adjacent to row R3.

IC layout diagram 800 includes a plurality of cells positioned in one or more of rows R1-R4. The cells include rectangular cells (not labeled for clarity), a non-rectangular cell NR1 positioned in rows R1 and R2, and a non-rectangular cell NR2 positioned in rows R3 and R4. In various embodiments, a non-rectangular cell NR1 or NR2 corresponds to one of cells 100-700B discussed above.

The sizes and shapes, e.g., number of rows spanned, of non-rectangular cells NR1 and NR2 depicted in FIG. 8 are non-limiting examples provided for the purpose of illustration. In various embodiments, IC layout diagram 800 includes one or more non-rectangular cells other than or in addition to one or both of non-rectangular cells NR1 and NR2, e.g., a cell spanning three of rows R1-R4.

In some embodiments, IC layout diagram 800 includes one or more electrical connections among the cells (not shown) whereby non-rectangular cells NR1 and/or NR2 are included in an IC configured to, in operation, perform one or more functions based in part on the low-level functions of non-rectangular cells NR1 and/or NR2.

By including one or more non-rectangular cells configured as discussed above, IC layout diagram 800 is capable of realizing the benefits discussed above with respect to FIGS. 1-7B.

FIG. 9 is a flowchart of method 900 of generating an IC layout diagram, in accordance with some embodiments. In some embodiments, generating the IC layout diagram includes generating some or all of one or more of IC layout diagrams 100-800 discussed above with respect to FIGS. 1-8.

In some embodiments, some or all of method 900 is executed by a processor of a computer. In some embodiments, some or all of method 900 is executed by a processor 1002 of IC layout diagram generation system 1000, discussed below with respect to FIG. 10.

In some embodiments, one or more operations of method 900 are a subset of operations of a method of forming an IC device. In some embodiments, one or more operations of method 900 are a subset of operations of an IC manufacturing flow, e.g., the IC manufacturing flow discussed below with respect to manufacturing system 1100 and FIG. 11.

In some embodiments, the operations of method 900 are performed in the order depicted in FIG. 9. In some embodiments, the operations of method 900 are performed simultaneously and/or in an order other than the order depicted in FIG. 9. In some embodiments, one or more operations are performed before, between, during, and/or after performing one or more operations of method 900.

In some embodiments, some of the operations of method 900 are performed as part of generating an IC layout diagram of a non-rectangular cell, e.g., a cell 100-700B discussed above. In some embodiments, some of the operations of method 900 are performed as part of generating an IC floorplan, e.g., IC layout diagram 800, including one or more instances of a non-rectangular cell, e.g., as part of an APR operation.

At operation 902, in some embodiments, an IC layout diagram is obtained from a storage device. In some embodiments, obtaining the IC layout diagram includes obtaining a rectangular cell from a storage device, e.g., a cell library. In some embodiments, obtaining the IC layout diagram includes obtaining a non-rectangular cell, e.g., a cell 100-700B discussed above, from the storage device.

In some embodiments, obtaining the IC layout diagram from the storage device includes obtaining the IC layout diagram from cell library 1007 discussed below with respect to FIG. 10.

At operation 904, in some embodiments, the cell is a rectangular cell and the cell is modified by arranging first and second rows of gate regions in the cell. Arranging the first and second rows includes the first row having a first width extending from first to last gate regions of the first row, whereby the first width is equal to a first multiple of a gate region pitch, and the second row being adjacent to the first row and having a second width extending from first to last gate regions of the second row, whereby the second width is equal to a second multiple of the gate region pitch greater than the first multiple.

In some embodiments, arranging the first and second rows includes arranging a first row of one or more first IC devices in a cell, the first row having a first width extending from first to last gate regions of the one or more first IC devices, and arranging a second row of one or more second IC devices in the cell adjacent to the first row, the second row having a second width extending from first to last gate regions of the one or more second IC devices.

In some embodiments, arranging the first and second rows includes arranging two of row R1 including gate regions GR extending from FG1 to LG1, row R2 including gate regions GR extending from FG2 to LG2, or row R3 including gate regions GR extending from FG3 to LG3, each having a width corresponding to a multiple of pitch GP, as discussed above with respect to FIGS. 1-7B.

In some embodiments, arranging the first and second rows includes arranging a total of three or more rows, e.g., rows R1-R3 as discussed above.

In various embodiments, arranging the first and second rows includes one of aligning each gate region of the first row with a corresponding gate region of the second row or aligning a subset of the gate regions of the first row with a corresponding gate region of the second row.

In some embodiments, arranging the first row includes the first row having a first height, e.g., one of heights CH1 or CH2 discussed above with respect to FIGS. 7A and 7B, and arranging the second row includes the second row having a second height different from the first height, e.g., the other of heights CH1 or CH2.

In some embodiments, arranging the first and second rows includes a sum of the first and second multiples being an odd number.

In some embodiments, arranging the first and second rows includes each of the first and last gate regions of one or both of the first or second rows being a dummy gate region.

In some embodiments, arranging the first row of gate regions includes modifying a rectangular cell, e.g., obtained in operation 902, by removing a dummy gate region outside the first to last gate regions of the first row.

In some embodiments, arranging the first row of gate regions includes modifying a rectangular cell, e.g., obtained in operation 902, by moving a gate region from one of the first or second rows to the other of the first or second rows.

In some embodiments, arranging the first and second rows includes modifying a rectangular cell, e.g., obtained in operation 902, and one or both of arranging the first row of one or more first IC devices or the arranging the second row of one or more second IC devices includes moving a critical device from a first location to a second location, e.g., moving an instance of critical device CD discussed above with respect to FIGS. 4, 5, 7A, and 7B or an instance of the clock source discussed above with respect to FIGS. 6A-6C.

In some embodiments, arranging the first or second row of one or more first or second IC devices includes configuring the one or more first or second IC devices as a clock source circuit, e.g., the clock source discussed above with respect to FIGS. 6A-6C.

In some embodiments, arranging the first row includes the first row having a first height corresponding to a first number of fins of FinFETs of the one or more first IC devices, arranging the second row includes the second row having a second height corresponding to a second number of fins of FinFETs of the one or more second IC devices, the first and second numbers of fins are different from each other, and the first and second heights are different from each other.

At operation 906, in some embodiments, after arranging the first and second rows, a non-rectangular cell is generated from the rectangular cell by defining first through fourth segments of a border of the cell. In some embodiments, defining the first through fourth segments includes extending the first segment along the first gate region of the first row, extending the second segment along the last gate region of the first row, extending the third segment along the first gate region of the second row, and extending the fourth segment along the last gate region of the second row, whereby the border of the cell is non-rectangular based on one or both of the first and third segments or the second and fourth segments being unaligned with each other.

In some embodiments, defining the first through fourth segments includes aligning the first and third segments with each other or aligning the second and fourth segments with each other. In some embodiments, extending the first segment includes aligning the first segment with a gate region of the second row other than the first or last gate region of the second row, and extending the second segment includes aligning the second segment with a gate region of the second row other than the first or last gate region of the second row.

In some embodiments, defining the first through fourth segments includes defining four or more of segments S1-S7 of border 100B discussed above with respect to FIG. 1.

In some embodiments, defining the first through fourth segments includes defining four or more segments of one of borders 200B-700BB discussed above with respect to FIGS. 2-7B.

In some embodiments, defining the first through fourth segments includes defining fifth through seventh segments of the cell border, e.g., by extending the fifth segment along the first width, extending the sixth segment along the second width, and extending the seventh segment along the second row a distance equal to a difference between the first and second widths.

At operation 908, in some embodiments, an electrical connection of the cell is configured. In some embodiments, configuring the electrical connection includes configuring an electrical connection capable of being electrically connected to an electrical connection external to the cell, e.g., as discussed above with respect to FIGS. 2 and 3.

In some embodiments, configuring the electrical connection includes configuring an internal electrical connection, e.g., as discussed above with respect to FIGS. 4 and 5.

In some embodiments, configuring the electrical connection includes configuring a signal path, e.g., signal path SP discussed above with respect to FIGS. 6A-6C.

In some embodiments, configuring the electrical connection includes intersecting a first subset of the first to last gate regions of the one or more second IC devices with a first metal layer region, overlapping first and second locations of the intersections of the first subset and the first metal layer region with first via regions, each first via region corresponding to an electrical connection between the corresponding gate region of the first subset and the first metal layer region, extending a second metal layer region across the first and second rows by intersecting the first metal layer region at a third location between the first and second locations, and overlapping the third location with a second via region corresponding to an electrical connection between the first and second metal layer regions.

In some embodiments, configuring the electrical connection includes arranging a third row of one or more third IC devices in the cell adjacent to the second row, the third row having a third width extending from first to last gate regions of the one or more third IC devices. Configuring the electrical connection also includes intersecting a second subset of the first to last gate regions of the one or more third IC devices with a third metal layer region, and overlapping fourth and fifth locations of the intersections of the second subset and the third metal layer region with third via regions. Each third via region corresponds to an electrical connection between the corresponding gate region of the second subset and the third metal layer region, the second metal layer region is extended across the third row by intersecting the third metal layer region at a sixth location between the fourth and fifth locations, and the sixth location is overlapped with a fourth via region corresponding to an electrical connection between the second and third metal layer regions.

At operation 910, in some embodiments, an APR operation including the cell is performed. A border of the cell, e.g., one of borders 100B-700BB discussed above with respect to FIGS. 1-7B, includes first and second segments extending along respective first and last gate regions of a first row of gate regions, a total number of the first row of gate regions being equal to a first multiple of a gate region pitch, third and fourth segments extending along respective first and last gate regions of a second row of gate regions adjacent to the first row of gate regions, a total number of the second row of gate regions being equal to a second multiple of the gate region pitch greater than the first multiple.

Performing the APR operation includes placing the cell in the IC layout diagram, e.g., IC layout diagram 800 discussed above with respect to FIG. 8, and arranging a plurality of electrical connections to the first and second rows of gate regions.

In some embodiments, placing the cell in the IC layout diagram includes positioning the first row of gate regions in a first row of the IC layout diagram corresponding to a first number of FinFET fins, and positioning the second row of gate regions in a second row of the IC layout diagram corresponding to a second number of FinFET fins different from the first number, e.g., as discussed above with respect to FIGS. 7A and 7B.

In some embodiments, arranging the plurality of electrical connections to the first and second rows of gate regions includes configuring an electrical connection to a metal region at a location in the first row of gate regions, wherein the metal region extends from the first row of gate regions to the second row of gate regions, e.g., as discussed above with respect to FIGS. 2 and 3.

At operation 912, in some embodiments, the IC layout diagram is stored in a storage device. In some embodiments, storing the IC layout diagram in the storage device includes storing the IC layout diagram in an IC layout diagram library, e.g., cell library 1007 or layout diagram library 1009 of IC layout diagram generation system 1000, discussed below with respect to FIG. 10.

In some embodiments, storing the IC layout diagram in the storage device includes storing the IC layout diagram in a non-volatile, computer-readable memory or a cell library, e.g., a database, and/or includes storing the IC layout diagram over a network. In some embodiments, storing the IC layout diagram in the storage device includes storing the IC layout diagram over network 1014 of IC layout diagram generation system 1000, discussed below with respect to FIG. 10.

In some embodiments, storing the IC layout diagram in the storage device includes performing one or more manufacturing operations based on the IC layout diagram. In some embodiments, performing one or more manufacturing operations includes performing one or more lithographic exposures based on the IC layout diagram. Performing one or more manufacturing operations, e.g., one or more lithographic exposures, based on the IC layout diagram is discussed below with respect to FIG. 11.

By executing some or all of the operations of method 900, an IC layout diagram is generated including one or more non-rectangular cells and is thereby capable of realizing the benefits discussed above with respect to IC layout diagrams 100-800.

FIG. 10 is a block diagram of an electronic design automation (EDA) system 1000 in accordance with some embodiments.

In some embodiments, EDA system 1000 includes an APR system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable storage medium 1004. Storage medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, storage medium 1004 stores computer program code 1006 configured to cause system 1000 (where such execution represents (at least in part) the EDA tool) to be usable for performing a portion or all of the noted processes and/or methods. In one or more embodiments, storage medium 1004 also stores information which facilitates performing a portion or all of the noted processes and/or methods. In one or more embodiments, storage medium 1004 stores cell library 1007 of IC layout cells including one or more of cells 100-700B as disclosed herein. In one or more embodiments, storage medium 1004 stores one or more layout diagrams 1009 corresponding to one or more layouts disclosed herein, e.g., IC layout 800 discussed above.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a user interface (UI) through I/O interface 1010. The information is stored in computer-readable medium 1004 as UI 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of an integrated circuit (IC) manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (fab) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122, e.g., including one or more of IC layout diagrams 100-800 discussed above with respect to FIGS. 1-8. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (RDF). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for photolithographic implementation effects during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments. fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thercon. Semiconductor wafer 1153 further includes one or more of various doped regions, dielectric features, multilevel interconnects, and the like (formed at subsequent manufacturing steps).

In some embodiments, a method of generating an IC layout diagram includes arranging a first row of gate regions in a cell, the first row having a first width extending from first to last gate regions of the first row, whereby the first width is equal to a first multiple of a gate region pitch, arranging a second row of gate regions in the cell adjacent to the first row, the second row having a second width extending from first to last gate regions of the second row, whereby the second width is equal to a second multiple of the gate region pitch greater than the first multiple, defining first through fourth segments of a border of the cell by extending the first segment along the first gate region of the first row, extending the second segment along the last gate region of the first row, extending the third segment along the first gate region of the second row, and extending the fourth segment along the last gate region of the second row, whereby the border of the cell is non-rectangular based on one or both of the first and third segments or the second and fourth segments being unaligned with each other, and storing an IC layout diagram of the cell in a storage device. In some embodiments, arranging the first and second rows includes aligning cach gate region of the first row with a corresponding gate region of the second row. In some embodiments, defining the first through fourth segments includes one of aligning the first and third segments with each other or aligning the second and fourth segments with each other. In some embodiments, extending the first segment includes aligning the first segment with a gate region of the second row other than the first or last gate region of the second row, and extending the second segment includes aligning the second segment with a gate region of the second row other than the first or last gate region of the second row. In some embodiments, the method includes defining fifth through seventh segments of the cell border by extending the fifth segment along the first width, extending the sixth segment along the second width, and extending the seventh segment along the second row a distance equal to a difference between the first and second widths. In some embodiments, the method includes arranging a third row of gate regions in the cell adjacent to the second row, the third row having a third width extending from first to last gate regions of the third row, whereby the third width is equal to a third multiple of the gate region pitch greater than the first multiple, and defining fifth and sixth segments of the cell border by extending the fifth segment along the first gate region of the third row, and extending the sixth segment along the last gate region of the third row. In some embodiments, arranging the first row includes the first row having a first height and arranging the second row comprises the second row having a second height different from the first height. In some embodiments, a sum of the first and second multiples is an odd number. In some embodiments, each of arranging the first row of gate regions and arranging the second row of gate regions includes each of the first and last gate regions being a dummy gate region. In some embodiments, the method includes obtaining the cell from the storage device or another storage device prior to the arranging the first and second rows of gate regions, wherein arranging the first row of gate regions includes removing a dummy gate region outside the first to last gate regions of the first row. In some embodiments, the method includes obtaining the cell from the storage device or another storage device prior to the arranging the first and second rows of gate regions, wherein arranging the first and second rows of gate regions includes moving a gate region from one of the first or second rows to the other of the first or second rows.

In some embodiments, a non-transitory, computer readable storage medium includes computer program code for one or more programs, the non-transitory, computer readable storage medium and the computer program code being configured to cause a processor to arrange a first row of one or more first IC devices in a cell, the first row having a first width extending from first to last gate regions of the one or more first IC devices, whereby the first width is equal to a first multiple of a gate region pitch, arrange a second row of one or more second IC devices in the cell adjacent to the first row, the second row having a second width extending from first to last gate regions of the one or more second IC devices, whereby the second width is equal to a second multiple of the gate region pitch greater than the first multiple, define first through fourth segments of a cell border by extending the first segment along the first gate region of the first row, extending the second segment along the last gate region of the first row, extending the third segment along the first gate region of the second row, and extending the fourth segment along the last gate region of the second row, whereby the border of the cell is non-rectangular based on one or both of the first and third segments or the second and fourth segments being unaligned with each other, and store an IC layout diagram of the cell in a storage device. In some embodiments, the non-transitory, computer readable storage medium and the computer program code are configured to cause the processor to further intersect a first subset of the first to last gate regions of the one or more second IC devices with a first metal layer region, overlap first and second locations of the intersections of the first subset and the first metal layer region with first via regions, each first via region corresponding to an electrical connection between the corresponding gate region of the first subset and the first metal layer region, extend a second metal layer region across the first and second rows by intersecting the first metal layer region at a third location between the first and second locations, and overlap the third location with a second via region corresponding to an electrical connection between the first and second metal layer regions. In some embodiments, the non-transitory, computer readable storage medium and the computer program code are configured to cause the processor to further arrange a third row of one or more third IC devices in the cell adjacent to the second row, the third row having a third width extending from first to last gate regions of the one or more third IC devices, intersect a second subset of the first to last gate regions of the one or more third IC devices with a third metal layer region, overlap fourth and fifth locations of the intersections of the second subset and the third metal layer region with third via regions, each third via region corresponding to an electrical connection between the corresponding gate region of the second subset and the third metal layer region, extend the second metal layer region across the third row by intersecting the third metal layer region at a sixth location between the fourth and fifth locations, and overlap the sixth location with a fourth via region corresponding to an electrical connection between the second and third metal layer regions. In some embodiments, the non-transitory, computer readable storage medium and the computer program code are configured to cause the processor to arrange the first row of one or more first IC devices by configuring the one or more first IC devices as a clock source circuit. In some embodiments, the non-transitory, computer readable storage medium and the computer program code are configured to cause the processor to arrange the first row by arranging the first row having a first height corresponding to a first number of fins of FinFETs of the one or more first IC devices, arrange the second row by arranging the second row having a second height corresponding to a second number of fins of FinFETs of the one or more second IC devices, wherein the first and second numbers of fins are different from each other, and the first and second heights are different from each other. In some embodiments, the non-transitory, computer readable storage medium and the computer program code are configured to cause the processor to further obtain the cell from the storage device or another storage device prior to arranging the first and second rows, wherein one or both of arranging the first row of one or more first IC devices or arranging the second row of one or more second IC devices includes moving a critical device from a first location to a second location.

In some embodiments, an EDA system includes a processor and a non-transitory, computer readable storage medium including computer program code for one or more programs, the non-transitory, computer readable storage medium and the computer program code being configured to, with the processor, cause the processor to obtain a cell from the non-transitory, computer readable storage medium or another storage medium, wherein the cell includes a non-rectangular border including first and second segments extending along respective first and last gate regions of a first row of gate regions, a total number of the first row of gate regions being equal to a first multiple of a gate region pitch, and third and fourth segments extending along respective first and last gate regions of a second row of gate regions adjacent to the first row of gate regions, a total number of the second row of gate regions being equal to a second multiple of the gate region pitch greater than the first multiple, perform an APR operation including placing the cell in an IC layout diagram; and arranging a plurality of electrical connections to the first and second rows of gate regions. In some embodiments, the non-transitory, computer readable storage medium and the computer program code are configured to, with the processor, cause the processor to place the cell in the IC layout diagram by positioning the first row of gate regions in a first row of the IC layout diagram corresponding to a first number of FinFET fins and positioning the second row of gate regions in a second row of the IC layout diagram corresponding to a second number of FinFET fins different from the first number. In some embodiments, the non-transitory, computer readable storage medium and the computer program code are configured to, with the processor, cause the processor to arrange the plurality of electrical connections by configuring an electrical connection to a metal region at a location in the first row of gate regions wherein the metal region extends from the first row of gate regions to the second row of gate regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of generating an integrated circuit (IC) layout diagram, the method comprising:
arranging a first row of gate regions in a cell, the first row having a first width extending from first to last gate regions of the first row, whereby the first width is equal to a first multiple of a gate region pitch;
arranging a second row of gate regions in the cell adjacent to the first row, the second row having a second width extending from first to last gate regions of the second row, whereby the second width is equal to a second multiple of the gate region pitch greater than the first multiple;
defining first through fourth segments of a border of the cell by:
extending the first segment along the first gate region of the first row,
extending the second segment along the last gate region of the first row,
extending the third segment along the first gate region of the second row, and
extending the fourth segment along the last gate region of the second row, whereby the border of the cell is non-rectangular based on one or both of the first and third segments or the second and fourth segments being unaligned with each other; and
storing an IC layout diagram of the cell in a storage device.

2. The method of claim 1, wherein the arranging the first and second rows comprises:
aligning each gate region of the first row with a corresponding gate region of the second row.

3. The method of claim 1, wherein the defining the first through fourth segments comprises one of:
aligning the first and third segments with each other; or
aligning the second and fourth segments with each other.

4. The method of claim 1, wherein
the extending the first segment comprises aligning the first segment with a gate region of the second row other than the first or last gate region of the second row, and
the extending the second segment comprises aligning the second segment with a gate region of the second row other than the first or last gate region of the second row.

5. The method of claim 1, further comprising defining fifth through seventh segments of the cell border by:
extending the fifth segment along the first width,
extending the sixth segment along the second width, and
extending the seventh segment along the second row a distance equal to a difference between the first and second widths.

6. The method of claim 1, further comprising:
arranging a third row of gate regions in the cell adjacent to the second row, the third row having a third width extending from first to last gate regions of the third row, whereby the third width is equal to a third multiple of the gate region pitch greater than the first multiple; and
defining fifth and sixth segments of the cell border by:
extending the fifth segment along the first gate region of the third row, and
extending the sixth segment along the last gate region of the third row.

7. The method of claim 1, wherein
the arranging the first row comprises the first row having a first height, and
the arranging the second row comprises the second row having a second height different from the first height.

8. The method of claim 1, wherein a sum of the first and second multiples is an odd number.

9. The method of claim 1, wherein
each of the arranging the first row of gate regions and the arranging the second row of gate regions comprises each of the first and last gate regions being a dummy gate region.

10. The method of claim 1, further comprising:
obtaining the cell from the storage device or another storage device prior to the arranging the first and second rows of gate regions,
wherein the arranging the first row of gate regions comprises removing a dummy gate region outside the first to last gate regions of the first row.

11. The method of claim 1, further comprising:
obtaining the cell from the storage device or another storage device prior to the arranging the first and second rows of gate regions,
wherein the arranging the first and second rows of gate regions comprises moving a gate region from one of the first or second rows to the other of the first or second rows.

12. A non-transitory, computer readable storage medium including computer program code for one or more programs, the non-transitory, computer readable storage medium and the computer program code being configured to cause a processor to:
arrange a first row of one or more first integrated circuit (IC) devices in a cell, the first row having a first width extending from first to last gate regions of the one or more first IC devices, whereby the first width is equal to a first multiple of a gate region pitch;
arrange a second row of one or more second IC devices in the cell adjacent to the first row, the second row having a second width extending from first to last gate regions of the one or more second IC devices, whereby the second width is equal to a second multiple of the gate region pitch greater than the first multiple;
define first through fourth segments of a cell border by:
extending the first segment along the first gate region of the first row,
extending the second segment along the last gate region of the first row,
extending the third segment along the first gate region of the second row, and
extending the fourth segment along the last gate region of the second row, whereby the border of the cell is non-rectangular based on one or both of the first and third segments or the second and fourth segments being unaligned with each other; and
store an IC layout diagram of the cell in a storage device.

13. The non-transitory, computer readable storage medium of claim 12,whereinthe non-transitory, computer readable storage medium and the computer program code are configured to cause the processor to further:
intersect a first subset of the first to last gate regions of the one or more second IC devices with a first metal layer region;
overlap first and second locations of the intersections of the first subset and the first metal layer region with first via regions, each first via region corresponding to an electrical connection between the corresponding gate region of the first subset and the first metal layer region;
extend a second metal layer region across the first and second rows by intersecting the first metal layer region at a third location between the first and second locations; and
overlap the third location with a second via region corresponding to an electrical connection between the first and second metal layer regions.

14. The non-transitory, computer readable storage medium of claim 13, wherein the non-transitory, computer readable storage medium and the computer program code are configured to cause the processor to further:
arrange a third row of one or more third IC devices in the cell adjacent to the second row, the third row having a third width extending from first to last gate regions of the one or more third IC devices;
intersect a second subset of the first to last gate regions of the one or more third IC devices with a third metal layer region;
overlap fourth and fifth locations of the intersections of the second subset and the third metal layer region with third via regions, each third via region corresponding to an electrical connection between the corresponding gate region of the second subset and the third metal layer region;
extend the second metal layer region across the third row by intersecting the third metal layer region at a sixth location between the fourth and fifth locations; and
overlap the sixth location with a fourth via region corresponding to an electrical connection between the second and third metal layer regions.

15. The non-transitory, computer readable storage medium of claim 12, wherein the non-transitory, computer readable storage medium and the computer program code are configured to cause the processor to arrange the first row of one or more first IC devices by configuring the one or more first IC devices as a clock source circuit.

16. The non-transitory, computer readable storage medium of claim 12, wherein the non-transitory, computer readable storage medium and the computer program code are configured to cause the processor to
arrange the first row by arranging the first row having a first height corresponding to a first number of fins of fin field-effect transistors (FinFETs) of the one or more first IC devices,
arrange the second row by arranging the second row having a second height corresponding to a second number of fins of FinFETs of the one or more second IC devices,
wherein
the first and second numbers of fins are different from each other, and
the first and second heights are different from each other.

17. The non-transitory, computer readable storage medium of claim 12, wherein the non-transitory, computer readable storage medium and the computer program code are configured to cause the processor to further:
obtain the cell from the storage device or another storage device prior to arranging the first and second rows,
wherein one or both of arranging the first row of one or more first IC devices or arranging the second row of one or more second IC devices comprises moving a critical device from a first location to a second location.

18. An electronic design automation (EDA) system comprising:
a processor; and
a non-transitory, computer readable storage medium including computer program code for one or more programs, the non-transitory, computer readable storage medium and the computer program code being configured to, with the processor, cause the processor to:
obtain a cell from the non-transitory, computer readable storage medium or another storage medium, wherein the cell comprises a non-rectangular border comprising:
first and second segments extending along respective first and last gate regions of a first row of gate regions, a total number of the first row of gate regions being equal to a first multiple of a gate region pitch; and
third and fourth segments extending along respective first and last gate regions of a second row of gate regions adjacent to the first row of gate regions, a total number of the second row of gate regions being equal to a second multiple of the gate region pitch greater than the first multiple;
perform an automatic placement and routing (APR) operation comprising:
placing the cell in an integrated circuit (IC) layout diagram; and
arranging a plurality of electrical connections to the first and second rows of gate regions.

19. The EDA system of claim 18, wherein the non-transitory, computer readable storage medium and the computer program code are configured to, with the processor, cause the processor to place the cell in the IC layout diagram by:
positioning the first row of gate regions in a first row of the IC layout diagram corresponding to a first number of fin field-effect transistors (FinFET) fins; and
positioning the second row of gate regions in a second row of the IC layout diagram corresponding to a second number of FinFET fins different from the first number.

20. The EDA system of claim 18, wherein the non-transitory, computer readable storage medium and the computer program code are configured to, with the processor, cause the processor to arrange the plurality of electrical connections by:
configuring an electrical connection to a metal region at a location in the first row of gate regions,
wherein the metal region extends from the first row of gate regions to the second row of gate regions.
